(19) United States
(12) Patent Application Publication
(10) Pub. No.: US 2026/0362787 A1
(43) Pub. Date: Nov. 12, 2026

(54) TRENCH METAL-OXIDE-SEMICONDUCTOR FIELD-EFFECT TRANSISTOR

(71) Applicant: POTENS SEMICONDUCTOR CORP., Hsinchu County (TW)

(72) Inventors: Hamilton Lu, Los Angeles, CA (US); Tung Ming Lai, Hsinchu County (TW); Hsiang Chi Meng, Hsinchu County (TW); Yung Sheng Ko, Hsinchu County (TW)

(73) Assignee: POTENS SEMICONDUCTOR CORP., Hsinchu County (TW)

(21) Appl. No.: 19/410,622

(22) Filed: Dec. 5, 2025

(30) Foreign Application Priority Data
May 8, 2025 (TW) 114117412

(51) Int. Cl. H10D 84/00

(52) U.S. Cl. CPC H10D 84/141

(57) ABSTRACT

The present disclosure is related to a trench metal-oxide-semiconductor field-effect transistor (MOSFET). First, a P-type semiconductor and an N-type semiconductor with high doping concentrations are embedded in a drift layer through ion implantation. The P-type semiconductor and the N-type semiconductor form an I-type junction at their interface. Energy levels of intra-band and inter-band quantum states generated at the I-type junction can absorb carriers generated in the device after irradiation, and tunneling electrons between the P-type semiconductor and the N-type semiconductor. This, combined with an effect of overlapping synchronized quantum states, causes a large number of quantum state energy levels to be created to absorb carriers, thereby effectively enhancing radiation resistance capability of the device. Additionally, the PIN or NIP diode can be embedded at various positions, such as at different positions fully within the drift layer, allowing trench MOSFETs to exhibit varying radiation resistance capabilities and on-resistance.

### CROSS-REFERENCE TO RELATED APPLICATION

The present disclosure claims priority to a Taiwan Patent Application No. 114117412 filed on May 18, 2025, the disclosure of which is incorporated in its entirety by reference herein.

### BACKGROUND OF THE DISCLOSURE

### Field of the Disclosure

The present disclosure particularly relates to a trench metal-oxide-semiconductor field-effect transistor (MOSFET) in which a PIN diode is embedded through ion implantation to enhance radiation resistance capability.

### Brief Description of Related Art

In response to demand for space technology development, effects of radiation and charged particles on semiconductor devices have become a critical research topic. Referring to FIG. 1, when a conventional metal-oxide-semiconductor field-effect transistor (MOSFET) is exposed to an environment of high-intensity radiation rays R, ionization occurs within a semiconductor structure, leading to generation of electron-hole (e-h) pairs. These e-h pairs are easily trapped by defect structures within the device. The defect structures include an interface between a semiconductor and a dielectric layer, the dielectric layer itself, or grain boundaries of a polycrystalline structure. Referring to FIG. 2, when the conventional MOSFET is turned on under applied voltage, negatively charged electrons e drift toward a drain at a bottom, where an externally applied potential is high (move in a direction opposite to an electric field), while positively charged holes h drift toward a gate or source, where an applied potential is low (move in a direction of the electric field). Because mobility of the holes h⁺ is lower than that of the electrons e⁻, induced electric charges (IEC) may continuously accumulate at the gate. This may cause the device to become permanently turned on or off, resulting in device failure. This type of long-term accumulated radiation effect is referred to as a total ionizing dose (TID) effect. Additionally, if at least one high-energy particle (such as at least one heavy ion or at least one proton) impacts a semiconductor oxide layer within a short period of time, localized ionization can be triggered, resulting in generation of a large number of charges and affecting the device. This phenomenon is referred to as a single event effect (SEE).

To prevent safety risks caused by device failure in semiconductor devices used in nuclear facilities or aerospace systems in high-radiation environments, it is crucial to assess extent of radiation-induced damage and radiation resistance capability of such devices. Accordingly, various radiation hardening (Rad-Hard) techniques have been developed in the industry to reduce sensitivity of semiconductor devices to radiation effects. For example, a cavity can be formed in a device, or a highly doped boron layer (deep boron layer, DBL) can be embedded in a chip using a special manufacturing process to intercept holes generated after irradiation, thereby preventing accumulation of the holes at defect structures and reducing a risk of device degradation. However, the aforementioned techniques still face certain challenges. For example, a cavity structure requires a wafer bonding process, which leads to reduced yield under mass production, and a radiation resistance effect of a DBL technique is also suboptimal. In view of the above, the prior art still needs improvement in terms of manufacturing difficulty and radiation resistance performance. Thus, how to effectively enhance radiation resistance capability of semiconductor devices to mitigate TID and SEE effects, while ensuring feasibility of mass production, remains a critical technical problem to be solved.

### SUMMARY OF THE DISCLOSURE

A main object of the present disclosure is to provide a trench metal-oxide-semiconductor field-effect transistor (MOSFET) with effectively enhanced radiation resistance capability.

To achieve the aforementioned object, in the present disclosure, a trench MOSFET includes a substrate, an N-type drift layer, a plurality of trench gates, a plurality of trench contact regions, a plurality of P-type well regions, a plurality of N-type source regions, and a plurality of PIN diodes. Mainly, in the present disclosure, the PIN diodes are formed in the N-type drift layer through ion implantation, wherein each of the PIN diodes includes an N-type semiconductor and a P-type semiconductor with high doping concentrations. This eliminates a need for a low-yield wafer bonding process. Furthermore, the high concentration doping allows a thinner I-type junction to be formed between the N-type semiconductor and the P-type semiconductor, resulting in a better quantum tunneling effect. This facilitates capturing of holes after irradiation, thereby enhancing radiation hardening (Rad-Hard). In addition, each of the PIN diodes can be embedded at various positions, such as at different positions fully within the N-type drift layer, at a position partially within the N-type drift layer and partially within the substrate, or at a position fully within the substrate, resulting in varying Rad-Hard effectiveness and on-resistance (RDS(on)), thereby meeting various user requirements.

### BRIEF DESCRIPTION OF THE DRAWINGS

FIG. 1 is a schematic diagram illustrating a conventional metal-oxide-semiconductor field-effect transistor (MOSFET) and radiation rays.

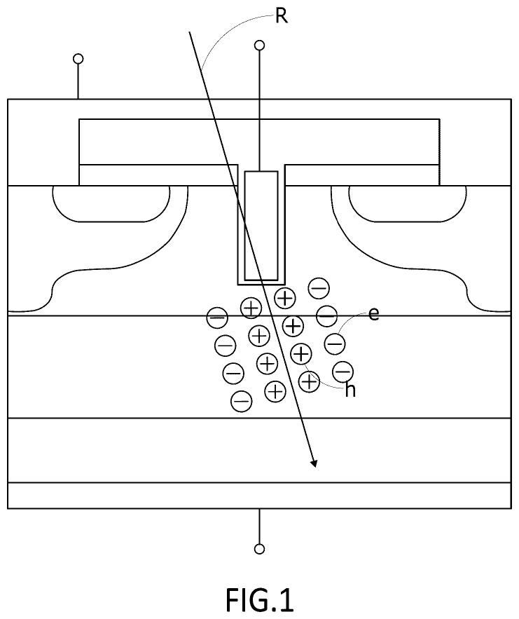

FIG. 2 is a schematic diagram illustrating the conventional MOSFET after irradiation with the radiation rays.

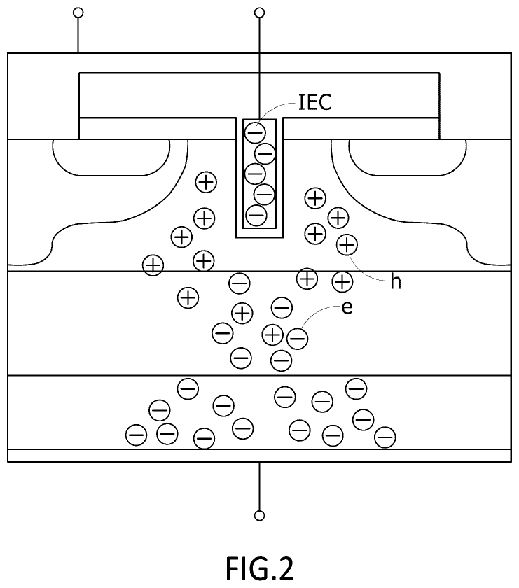

FIG. 3 is a schematic diagram illustrating an N-channel MOSFET structure according to the present disclosure.

FIG. 4 is a schematic diagram (1) illustrating an N-channel MOSFET structure according to an embodiment of the present disclosure.

FIG. 5 is a schematic diagram of implementation according to the present disclosure.

FIG. 6 is a simulated experimental data chart according to the present disclosure.

FIG. 7 is a schematic diagram (2) illustrating an N-channel MOSFET structure according to an embodiment of the present disclosure.

FIG. 8 is a schematic diagram (3) illustrating an N-channel MOSFET structure according to an embodiment of the present disclosure.

FIG. 9 is a schematic diagram (1) illustrating an N-channel MOSFET structure using SiC material according to the present disclosure.

FIG. 10 is a schematic diagram (2) illustrating an N-channel MOSFET structure using SiC material according to the present disclosure.

FIG. 11 is a schematic diagram (1) illustrating a P-channel MOSFET structure according to the present disclosure.

FIG. 12 is a schematic diagram (2) illustrating a P-channel MOSFET structure according to the present disclosure.

### DETAILED DESCRIPTION OF PREFERRED EMBODIMENTS

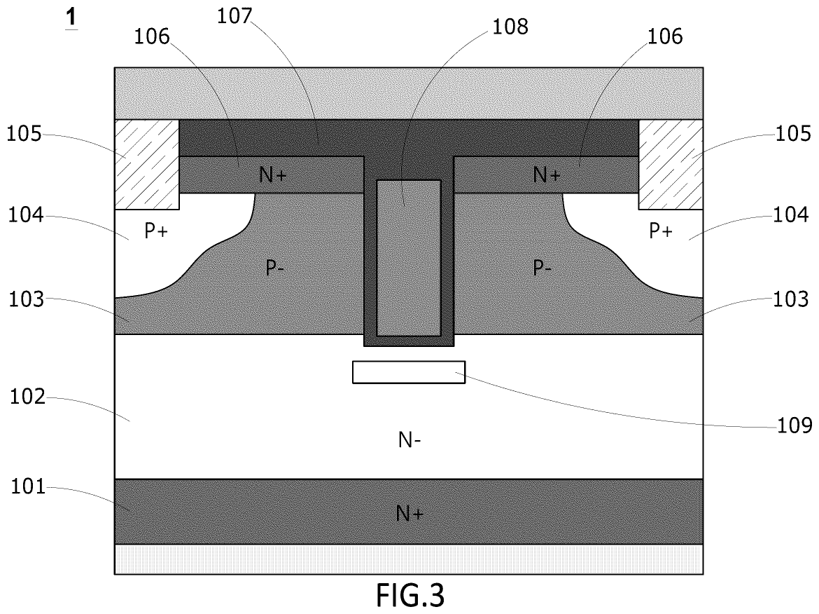

Referring to FIG. 3, in the present disclosure, a trench metal-oxide-semiconductor field-effect transistor (MOSFET) 1 is arranged with a plurality of trench gates, a plurality of trench contact regions, and a plurality of vertical PN junctions. Compared to a planar MOSFET, this design, due to its higher channel density, maintains breakdown voltage while reducing on-resistance (RDS(on)) and gate charges Qg. Additionally, the trench MOSFET 1 in the present disclosure includes a substrate 101 doped with an N-type conduction agent at a high doping concentration to serve as a drain for conduction; an N-type drift layer 102 formed over the substrate 101 by epitaxy using the N-type conduction agent at a low doping concentration; a plurality of P-type well regions 103, wherein each of the P-type well regions 103 is implanted with a P-type conduction agent at a low doping concentration through ion implantation after a lithography process on the N-type drift layer 102, and formed over the N-type drift layer 102, such that the P-type well regions 103 are positioned over the N-type drift layer 102 to form a plurality of PN junctions; a plurality of P-type contact regions 104, wherein each of the P-type contact regions 104 is implanted with the P-type conduction agent and formed over the corresponding P-type well region 103; a plurality of N-type source regions 106, wherein each of the N-type source regions 106 is implanted with the N-type conduction agent at a high doping concentration and formed over the corresponding P-type well region 103; a plurality of trench contact regions 105, wherein each of the trench contact regions 105 is formed laterally between the corresponding N-type source regions 106; a plurality of dielectric layers 107 formed over the corresponding P-type well regions 103 using a technique such as thermal oxidation or chemical vapor deposition (CVD); a plurality of trench gate layers 108, wherein each of the trench gate layers 108 is formed over the N-type drift layer 102 and can be made of polysilicon, but the present disclosure is not limited thereto; and a plurality of I-type regions 109, wherein each of the I-type regions 109 is embedded in the N-type drift layer 102 and implanted with at least one doped ion. Each of the at least one doped ion can, for example, be an argon (Ar) ion. Because the I-type regions 109 have many quantum states, when the trench MOSFET 1 is irradiated with radiation rays R, the quantum states in the I-type regions 109 can absorb holes h generated after irradiation with the radiation rays R. Thus, the use of I-type regions 109 can effectively prevent the holes h from being trapped in defect structures of the transistor and reduce induced electric charges (IEC) accumulated at the gate that can lead to device failure.

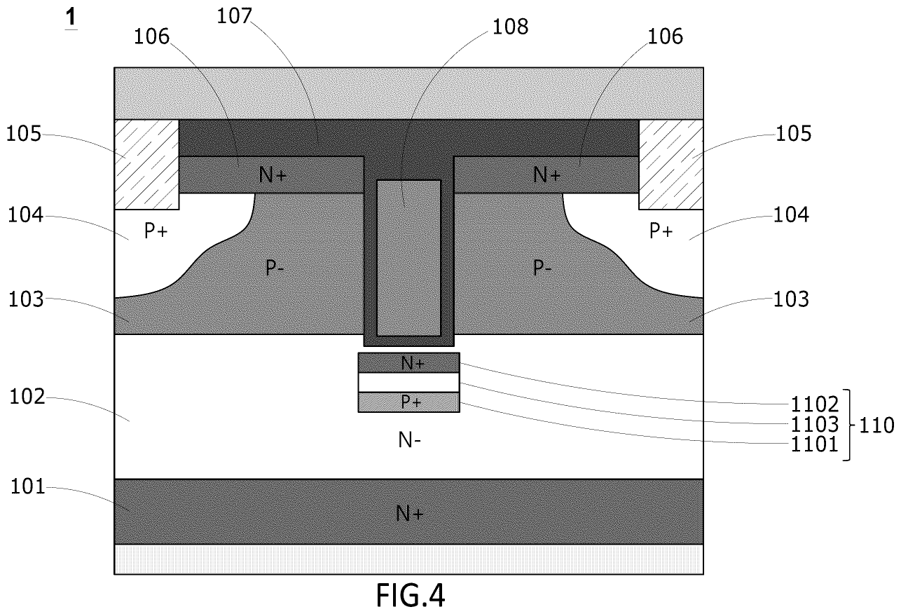

Referring to FIG. 4, the I-type regions 109 in the trench MOSFET 1 in the present disclosure can alternatively be replaced with PIN (or NIP) diodes 110, which are embedded in the N-type drift layer 102. Each of the PIN diodes 110 includes a P-type semiconductor 1101 and an N-type semiconductor 1102. Each of the PIN diodes 110 may be a single diode formed by the P-type semiconductor 1101 and the N-type semiconductor 1102. Alternatively, each of the PIN diodes 110 may be multiple diodes in series, wherein each of the multiple diodes is similar to the single diode. The P-type semiconductor 1101 is embedded in the N-type drift layer 102 through ion implantation, and the N-type semiconductor 1102 is implanted and formed on the top of the P-type semiconductor 1101. The P-type semiconductor 1101 and the N-type semiconductor 1102 are in contact, forming an I-type junction 1103. When a forward voltage is applied to each of the PIN diodes 110, electrons e pass from the N-type semiconductor 1102 through the I-type junction 1103 to the P-type semiconductor 1101 via a quantum tunneling effect, thereby capturing holes h generated after irradiation. The higher the doping concentrations of the P-type semiconductor 1101 and the N-type semiconductor 1102, the more quantum states exist at the I-type junction 1103 between the P-type semiconductor 1101 and the N-type semiconductor 1102. This results in an increased number of charge carriers (electrons e or holes h) entering a conduction band, allowing more electrons e to tunnel into the P-type semiconductor 1101. Additionally, the I-type junction 1103 is selectively formed through ion implantation using a dopant. The dopant can, for example, be at least one Ar ion. The at least one Ar ion is implanted between the P-type semiconductor 1101 and the N-type semiconductor 1102, increasing the number of quantum states at the I-type junction 1103. Moreover, the higher the doping concentrations of the P-type semiconductor 1101 and the N-type semiconductor 1102, the thinner the thickness of the I-type junction 1103 formed at their contact. Thickness of the N-type drift layer 102, the P-type well regions 103, the P-type semiconductors 1101, and the N-type semiconductors 1102 can be adjusted according to desired breakdown voltage of the trench MOSFET 1. The P-type conduction agent can, for example, be boron (B) ions, indium (In) ions, or gallium (Ga) ions, and the N-type conduction agent can, for example, be phosphorus (P) ions, arsenic (As) ions, or antimony (Sb) ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” (a plus sign in mathematical notation) or “−” (a minus sign in mathematical notation), where “+” indicates a higher relative concentration, “−” indicates a lower relative concentration, and absence of “+” or “−” represents a relative concentration between the two.

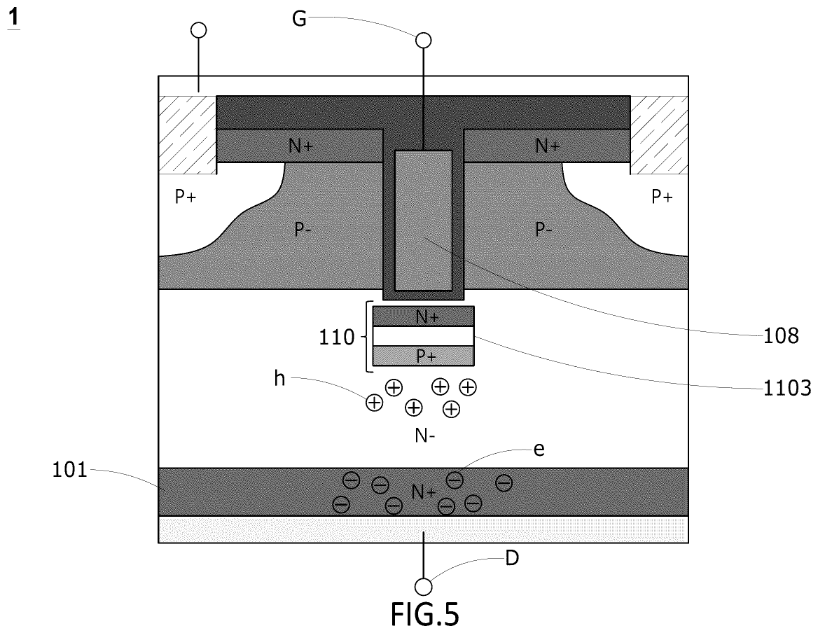

Referring to FIG. 5, after the trench MOSFET 1 in the present disclosure is irradiated with the radiation rays R, electrons e generated by excitation drift along a direction opposite to the electric field toward the substrate 101 which is electrically connected to a drain terminal D, while generated holes h drift along a direction of the electric field toward each of the trench gate layers 108 which is electrically connected to a gate terminal G. The holes h are attracted by the electrons e at the I-type junction 1103 of each of the PIN diodes 110 and are subsequently captured and filled. Thus, each of the PIN diodes 110 can be used to absorb the holes h generated after irradiation with the radiation rays R, effectively preventing the holes h from being trapped in defect structures of the transistor and reducing IEC accumulated at the gate that can lead to device failure.

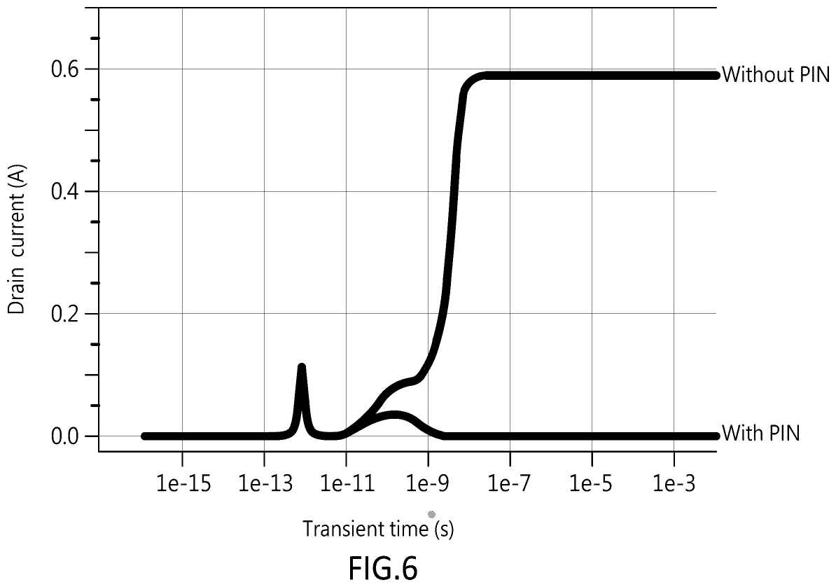

Referring to FIG. 6, within 1e-11 seconds after a single event effect (SEE) occurs, drain current of a device with a structure of the PIN diodes 110 in the present disclosure for radiation protection is significantly reduced compared to that of a device without the structure of the PIN diodes 110 for radiation protection. The drain current of the device without the structure of the PIN diodes 110 rises to nearly 0.6 A after 1e-11 seconds, whereas the drain current of the device with the structure of the PIN diodes 110 remains below 0.05 A after 1e-11 seconds. Accordingly, using the structure of the PIN diodes 110 for radiation protection in the trench MOSFET 1 can indeed significantly lower the drain current of the device after the device is irradiated with the radiation rays R.

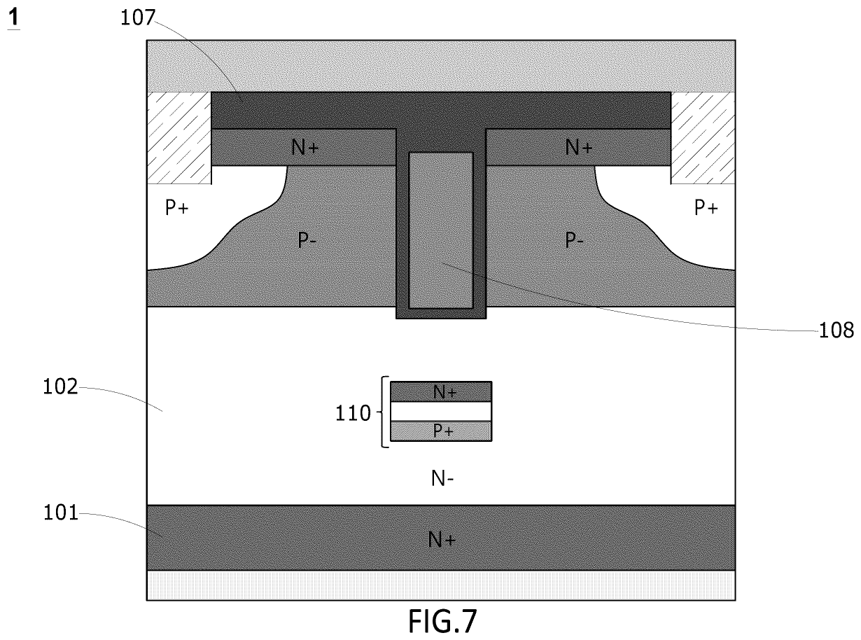

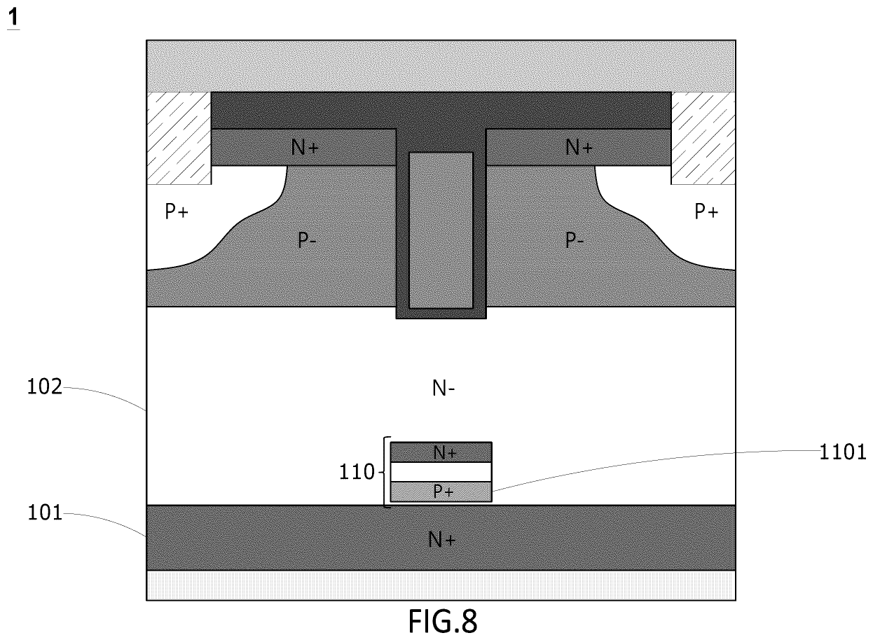

Referring to FIG. 7 and FIG. 4, radiation-hardening effectiveness varies depending on a vertical implantation position of each of the PIN diodes 110. When each of the PIN diodes 110 is implanted at an upper position within the N-type drift layer 102 (as illustrated in FIG. 4), because holes h generated after circuit conduction drift toward the corresponding trench gate layer 108, optimal hole h-trapping efficiency is achieved. However, this configuration exhibits relatively higher on-resistance. When each of the PIN diodes 110 is implanted at a middle position within the N-type drift layer 102 (as illustrated in FIG. 7), although hole h-trapping efficiency of each of the PIN diodes 110 is not as high as that achieved at the upper position within the N-type drift layer 102, on-resistance is relatively lower. Referring to FIG. 8, when each of the PIN diodes 110 is implanted at a lower position within the N-type drift layer 102, and the P-type semiconductor 1101 is implanted and formed over the substrate 101, hole h-trapping efficiency of each of the PIN diodes 110 is the lowest among the three configurations, yet this configuration has the lowest on-resistance and minimal power loss. Users can implant each of the PIN diodes 110 at a suitable position according to their requirements to effectively capture holes h generated after irradiation while reducing power loss. In the aforementioned embodiments, each of the PIN diodes 110 is implanted fully within the N-type drift layer 102. Alternatively, each of the PIN diodes 110 is implanted partially within the N-type drift layer 102 and partially within the substrate 101. Still alternatively, each of the PIN diodes 110 is implanted fully within the substrate 101.

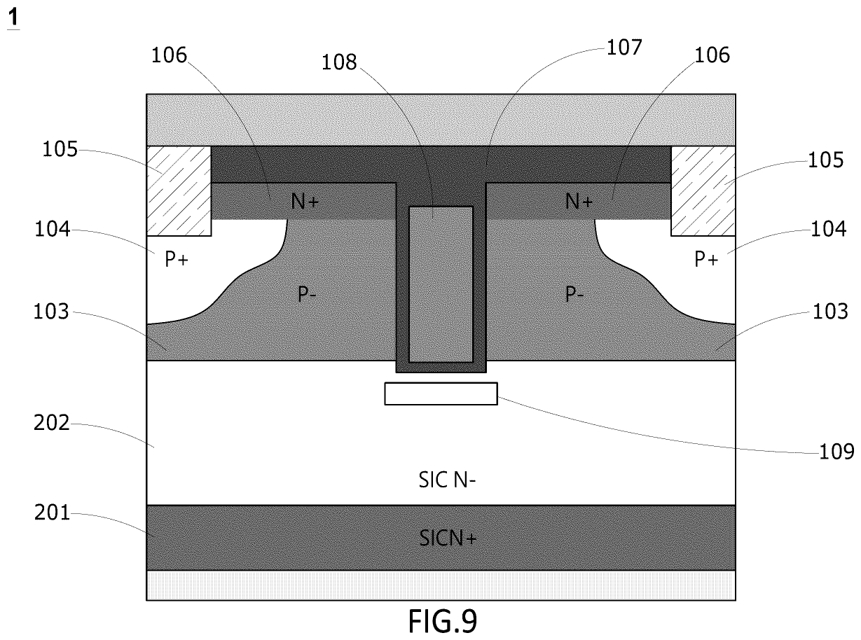

Referring to FIG. 9, an embodiment of the present disclosure may alternatively be implemented using silicon carbide (SiC) material. As illustrated in the figure, the trench MOSFET 1 in the present disclosure includes a SiC substrate 201 doped with an N-type conduction agent at a high doping concentration to serve as a drain for conduction; an N-type SiC drift layer 202 formed over the SiC substrate 201 by epitaxial deposition using the N-type conduction agent at a low doping concentration; a plurality of P-type well regions 103, wherein each of the P-type well regions 103 is implanted with a P-type conduction agent at a low doping concentration through ion implantation after a lithography process on the N-type SiC drift layer 202, and formed over the N-type SiC drift layer 202, such that the P-type well regions 103 are positioned over the N-type SiC drift layer 202 to form a plurality of PN junctions; a plurality of P-type contact regions 104, wherein each of the P-type contact regions 104 is implanted with the P-type conduction agent and formed over the corresponding P-type well region 103; a plurality of N-type source regions 106, wherein each of the N-type source regions 106 is implanted with the N-type conduction agent at a high doping concentration and formed over the corresponding P-type well region 103; a plurality of trench contact regions 105, wherein each of the trench contact regions 105 is formed laterally between the corresponding N-type source regions 106; a plurality of dielectric layers 107 formed over the corresponding P-type well regions 103 using a technique such as thermal oxidation or CVD; a plurality of trench gate layers 108, wherein each of the trench gate layers 108 is formed over the N-type SiC drift layer 202 and can be made of polysilicon, but the present disclosure is not limited thereto; and a plurality of I-type regions 109, wherein each of the I-type regions 109 is embedded in the N-type SiC drift layer 202 and implanted with at least one doped ion. Each of the at least one doped ion can, for example, be an Ar ion. Because the I-type regions 109 have many quantum states, when the trench MOSFET 1 is irradiated with radiation rays R, the quantum states in the I-type regions 109 can absorb holes h generated after irradiation with the radiation rays R. Thus, the use of I-type regions 109 can effectively prevent the holes h from being trapped in defect structures of the transistor and reduce IEC accumulated at the gate that can lead to device failure.

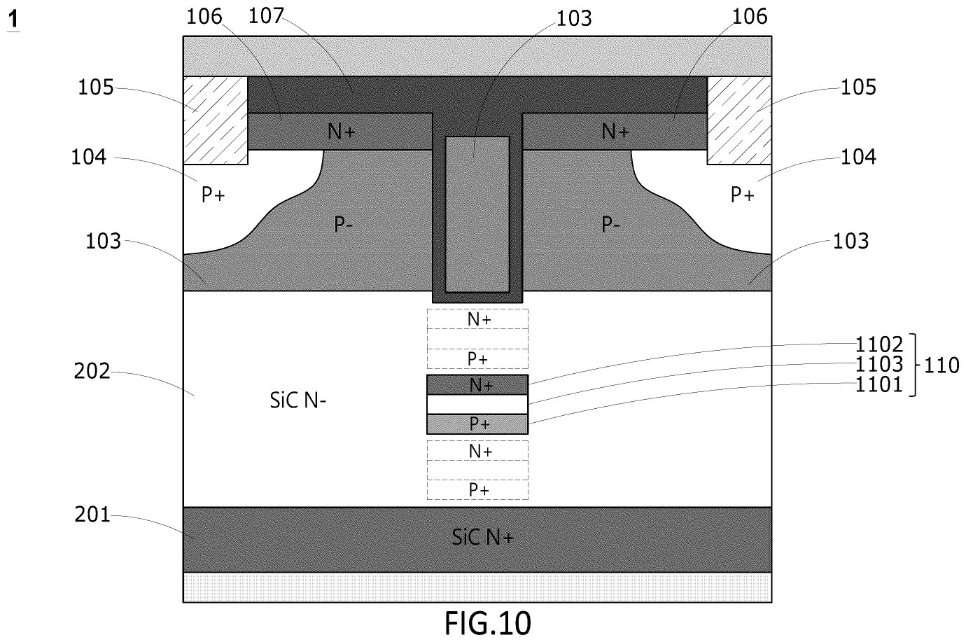

Referring to FIG. 10, the aforementioned I-type regions 109 in the trench MOSFET 1 in the present disclosure can alternatively be replaced with PIN diodes 110, which are embedded in the N-type SiC drift layer 202. Each of the PIN diodes 110 includes a P-type semiconductor 1101 and an N-type semiconductor 1102. Each of the PIN diodes 110 may be a single diode formed by the P-type semiconductor 1101 and the N-type semiconductor 1102. Alternatively, each of the PIN diodes 110 may be multiple diodes in series, wherein each of the multiple diodes is similar to the single diode. The P-type semiconductor 1101 is embedded in the N-type SiC drift layer 202 through ion implantation, and the N-type semiconductor 1102 is implanted and formed on the top of the P-type semiconductor 1101. The P-type semiconductor 1101 and the N-type semiconductor 1102 are in contact, forming an I-type junction 1103. When a forward voltage is applied to each of the PIN diodes 110, electrons e pass from the N-type semiconductor 1102 through the I-type junction 1103 to the P-type semiconductor 1101 via a quantum tunneling effect, thereby capturing holes h generated after irradiation with radiation rays R. The higher the doping concentrations of the P-type semiconductor 1101 and the N-type semiconductor 1102, the more quantum states exist at the I-type junction 1103 between the P-type semiconductor 1101 and the N-type semiconductor 1102. This results in an increased number of charge carriers (electrons e or holes h) entering a conduction band, allowing more electrons e to tunnel into the P-type semiconductor 1101. Additionally, the I-type junction 1103 is selectively formed through ion implantation using a dopant. The dopant can, for example, be at least one Ar ion. The at least one Ar ion is implanted between the P-type semiconductor 1101 and the N-type semiconductor 1102, increasing the number of quantum states at the I-type junction 1103. Moreover, the higher the doping concentrations of the P-type semiconductor 1101 and the N-type semiconductor 1102, the thinner the thickness of the I-type junction 1103 formed at their contact. Thickness of the N-type SiC drift layer 202, the P-type well regions 103, the P-type semiconductors 1101, and the N-type semiconductors 1102 can be adjusted according to desired breakdown voltage of the trench MOSFET 1. The P-type conduction agent can, for example, be boron (B) ions, indium (In) ions, or gallium (Ga) ions, and the N-type conduction agent can, for example, be phosphorus (P) ions, arsenic (As) ions, or antimony (Sb) ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” (a plus sign in mathematical notation) or “−” (a minus sign in mathematical notation), where “+” indicates a higher relative concentration, “−” indicates a lower relative concentration, and absence of “+” or “−” represents a relative concentration between the two.

Based on the above, the trench MOSFET 1 in the present disclosure provides varying radiation-hardening effectiveness depending on a vertical implantation position of each of the PIN diodes 110. When each of the PIN diodes 110 is implanted at an upper position within the N-type SiC drift layer 202, because holes h generated after circuit conduction drift toward the corresponding trench gate layer 108, optimal hole h-trapping efficiency is achieved. However, this configuration exhibits relatively higher on-resistance. When each of the PIN diodes 110 is implanted at a middle position within the N-type SiC drift layer 202, although hole h-trapping efficiency of each of the PIN diodes 110 is not as high as that achieved at the upper position within the N-type SiC drift layer 202, on-resistance is relatively lower. When each of the PIN diodes 110 is implanted at a lower position within the N-type SiC drift layer 202, and the P-type semiconductor 1101 is implanted and formed over the SiC substrate 201, hole h-trapping efficiency of each of the PIN diodes 110 is the lowest among the three configurations, yet this configuration has the lowest on-resistance and minimal power loss. Users can implant each of the PIN diodes 110 at a suitable position according to their requirements to effectively capture holes h generated after irradiation while reducing power loss. In the aforementioned embodiments, each of the PIN diodes 110 is implanted fully within the N-type SiC drift layer 202. Alternatively, each of the PIN diodes 110 is implanted partially within the N-type SiC drift layer 202 and partially within the SiC substrate 201. Still alternatively, each of the PIN diodes 110 is implanted fully within the SiC substrate 201.

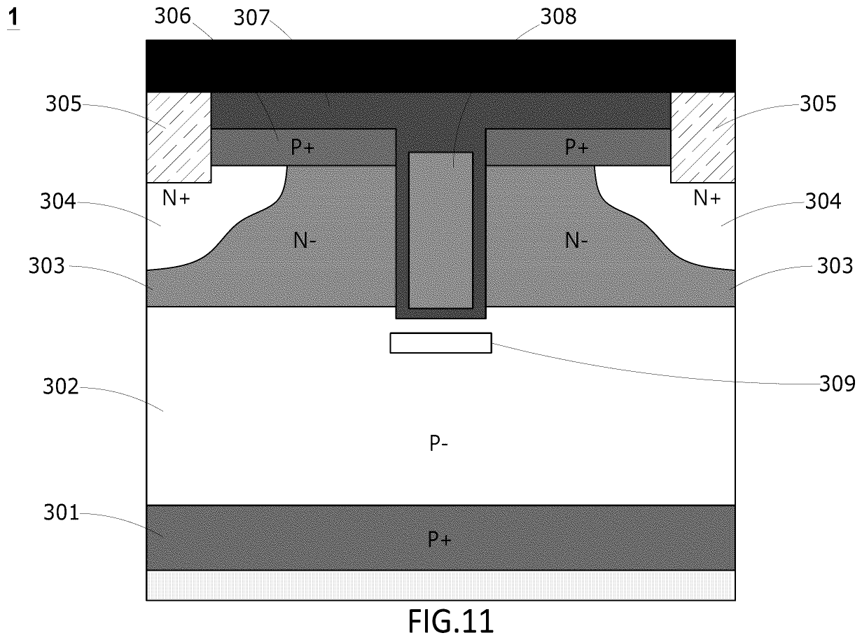

Referring to FIG. 11, the aforementioned trench MOSFETs are illustrated by way of example using N-channel MOSFET embodiments, and may alternatively be illustrated using P-channel MOSFET embodiments. As illustrated in the figure, the trench MOSFET 1 in the present disclosure includes a substrate 301 doped with a P-type conduction agent at a high doping concentration to serve as a drain for conduction, wherein the substrate 301 can be made of silicon (Si) or SiC, but the present disclosure is not limited thereto; a P-type drift layer 302, wherein the P-type drift layer 302 can be made of Si or SiC, but the present disclosure is not limited thereto, and wherein the P-type drift layer 302 is formed over the substrate 301 by epitaxial deposition using the P-type conduction agent at a low doping concentration ; a plurality of N-type well regions 303, wherein each of the N-type well regions 303 is implanted with an N-type conduction agent at a low doping concentration through ion implantation after a lithography process on the P-type drift layer 302, and formed over the P-type drift layer 302, such that the N-type well regions 303 are positioned over the P-type drift layer 302 to form a plurality of PN junctions; a plurality of N-type contact regions 304, wherein each of the N-type contact regions 304 is implanted with the N-type conduction agent and formed over the corresponding N-type well region 303; a plurality of P-type source regions 306, wherein each of the P-type source regions 306 is implanted with the P-type conduction agent at a high doping concentration and formed over the corresponding N-type well region 303; a plurality of trench contact regions 305, wherein each of the trench contact regions 305 is formed laterally between the corresponding P-type source regions 306; a plurality of dielectric layers 307 formed over the corresponding N-type well regions 303 using a technique such as thermal oxidation or CVD; a plurality of trench gate layers 308, wherein each of the trench gate layers 308 is formed over the P-type drift layer 302 and can be made of polysilicon, but the present disclosure is not limited thereto; and a plurality of I-type regions 309, wherein each of the I-type regions 309 is embedded in the P-type drift layer 302 and implanted with at least one doped ion. Each of the at least one doped ion can, for example, be an Ar ion. Because the I-type regions 309 have many quantum states, when the trench MOSFET 1 is irradiated with radiation rays R, the quantum states in the I-type regions 309 can absorb holes h generated after irradiation with the radiation rays R. Thus, the use of I-type regions 309 can effectively prevent the holes h from being trapped in defect structures of the transistor and reduce IEC accumulated at the gate that can lead to device failure.

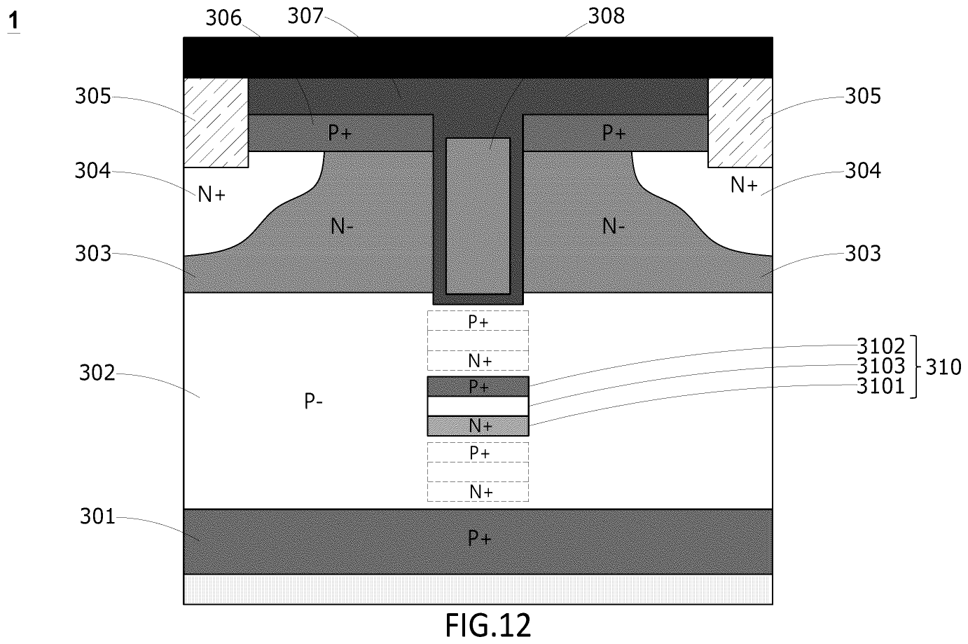

Referring to FIG. 12, the aforementioned I-type regions 309 in the trench MOSFET 1 in the present disclosure can alternatively be replaced with NIP diodes 310, which are embedded in the P-type drift layer 302. Each of the NIP diodes 310 includes an N-type semiconductor 3101 and a P-type semiconductor 3102. Each of the NIP diodes 310 may be a single diode formed by the N-type semiconductor 3101 and the P-type semiconductor 3102. Alternatively, each of the NIP diodes 310 may be multiple diodes in series, wherein each of the multiple diodes is similar to the single diode. The N-type semiconductor 3101 is embedded in the P-type drift layer 302 through ion implantation, and the P-type semiconductor 3102 is implanted and formed on the top of the N-type semiconductor 3101. The N-type semiconductor 3101 and the P-type semiconductor 3102 are in contact, forming an I-type junction 3103. When a forward voltage is applied to each of the NIP diodes 310, electrons e pass from the P-type semiconductor 3102 through the I-type junction 3103 to the N-type semiconductor 3101 via a quantum tunneling effect, thereby capturing holes h generated after irradiation with radiation rays R. The higher the doping concentrations of the N-type semiconductor 3101 and the P-type semiconductor 3102, the more quantum states exist at the I-type junction 3103 between the N-type semiconductor 3101 and the P-type semiconductor 3102. This results in an increased number of charge carriers (electrons e or holes h) entering a conduction band, allowing more electrons e to tunnel into the N-type semiconductor 3101. Additionally, the I-type junction 3103 is selectively formed through ion implantation using a dopant. The dopant can, for example, be at least one Ar ion. The at least one Ar ion is implanted between the N-type semiconductor 3101 and the P-type semiconductor 3102, increasing the number of quantum states at the I-type junction 3103. Moreover, the higher the doping concentrations of the N-type semiconductor 3101 and the P-type semiconductor 3102, the thinner the thickness of the I-type junction 3103 formed at their contact. Thickness of the P-type drift layer 302, the N-type well regions 303, the N-type semiconductors 3101, and the P-type semiconductors 3102 can be adjusted according to desired breakdown voltage of the trench MOSFET 1. The P-type conduction agent can, for example, be boron (B) ions, indium (In) ions, or gallium (Ga) ions, and the N-type conduction agent can, for example, be phosphorus (P) ions, arsenic (As) ions, or antimony (Sb) ions, but the present disclosure is not limited thereto. The N-type conduction agent (as indicated by “N” in the figure) and the P-type conduction agent (as indicated by “P” in the figure) have opposite electrical polarities. Additionally, a concentration of each of the conduction agents is denoted using a symbol “+” (a plus sign in mathematical notation) or “−” (a minus sign in mathematical notation), where “+” indicates a higher relative concentration, “−” indicates a lower relative concentration, and absence of “+” or “−” represents a relative concentration between the two.

Based on the above, the trench MOSFET 1 in the present disclosure provides varying radiation-hardening effectiveness depending on a vertical implantation position of each of the NIP diodes 310. When each of the NIP diodes 310 is implanted at an upper position within the P-type drift layer 302, because holes h generated after circuit conduction drift toward the corresponding trench gate layer 308, optimal hole h-trapping efficiency is achieved. However, this configuration exhibits relatively higher on-resistance. When each of the NIP diodes 310 is implanted at a middle position within the P-type drift layer 302, although hole h-trapping efficiency of each of the NIP diodes 310 is not as high as that achieved at the upper position within the P-type drift layer 302, on-resistance is relatively lower. When each of the NIP diodes 310 is implanted at a lower position within the P-type drift layer 302, and the N-type semiconductor 3101 is implanted and formed over the substrate 301, hole h-trapping efficiency of each of the NIP diodes 310 is the lowest among the three configurations, yet this configuration has the lowest on-resistance and minimal power loss. Users can implant each of the NIP diodes 310 at a suitable position according to their requirements to effectively capture holes h generated after irradiation with the radiation rays R while reducing power loss. In the aforementioned embodiments, each of the NIP diodes 310 is implanted fully within the P-type drift layer 302. Alternatively, each of the NIP diodes 310 is implanted partially within the P-type drift layer 302 and partially within the substrate 301. Still alternatively, each of the NIP diodes 310 is implanted fully within the substrate 301.

As mentioned above, mainly, in a trench MOSFET of the present disclosure, PIN/NIP diodes are embedded within a drift layer through ion implantation. In each of the PIN/NIP diodes, both a P-type semiconductor and an N-type semiconductor are highly doped, forming an I-type junction when the two are in contact. This configuration effectively captures holes generated after irradiation through a quantum tunneling effect. This not only simplifies a device manufacturing process but also significantly enhances radiation hardening (Rad-Hard) under mass production of semiconductor devices, thereby improving conditions of total ionizing dose (TID) and single event effect (SEE). Accordingly, upon implementation, the present disclosure indeed achieves an object of providing a trench MOSFET with effectively enhanced radiation resistance capability.

The above is only the preferred embodiments of the present disclosure, and is not intended to limit the present disclosure to the forms disclosed. Any modifications, equivalent alternatives, and improvements made within the spirit and the scope of present disclosure by persons skilled in the art should be included in the scope of claims of the present disclosure.

### REFERENCE NUMERALS IN DRAWINGS

1 a trench MOSFET
101 a substrate
102 an N-type drift layer
103 a P-type well region
104 a P-type contact region
105 a trench contact region
106 an N-type source region
107 a dielectric layer
108 a trench gate layer
109 an I-type region
110 a PIN diode
1101 a P-type semiconductor
1102 an N-type semiconductor
1103 an I-type junction
201 a SiC substrate
202 an N-type SiC drift layer
301 a substrate
302 a P-type drift layer
303 an N-type well region
304 an N-type contact region
305 a trench contact region
306 a P-type source region
307 a dielectric layer
308 a trench gate layer
309 an I-type region
310 an NIP diode
3101 an N-type semiconductor
3102 a P-type semiconductor
3103 an I-type junction
IEC induced electric charges
R a radiation ray
h holes
e electrons
G a gate terminal
D a drain terminal
S a source terminal

What is claimed is:

1. A trench metal-oxide-semiconductor field-effect transistor (MOSFET), comprising:
a substrate doped with an N-type conduction agent at a high doping concentration;
an N-type drift layer doped with the N-type conduction agent at a low doping concentration and extending over the substrate;
a plurality of P-type well regions, wherein each of the P-type well regions is doped with a P-type conduction agent at a low doping concentration and extends within the N-type drift layer;
a plurality of P-type contact regions, wherein each of the P-type contact regions is implanted with the P-type conduction agent and formed over the corresponding P-type well region;
a plurality of N-type source regions, wherein each of the N-type source regions is implanted with the N-type conduction agent at a high doping concentration and formed over the corresponding P-type well region;
a plurality of dielectric layers formed over the corresponding P-type well regions;
a plurality of trench gate layers formed over the N-type drift layer; and
a plurality of I-type regions, wherein each of the I-type regions is embedded in the N-type drift layer and implanted with at least one doped ion.

2. The trench MOSFET of claim 1, wherein each of the at least one doped ion in each of the I-type regions is an argon ion.

3. The trench MOSFET of claim 1, wherein material of the substrate and the N-type drift layer is silicon (Si) or silicon carbide (SiC).

4. A trench metal-oxide-semiconductor field-effect transistor (MOSFET), comprising:
a substrate doped with an N-type conduction agent at a high doping concentration;
an N-type drift layer doped with the N-type conduction agent at a low doping concentration and extending over the substrate;
a plurality of P-type well regions, wherein each of the P-type well regions is doped with a P-type conduction agent at a low doping concentration and extends within the N-type drift layer;
a plurality of P-type contact regions, wherein each of the P-type contact regions is implanted with the P-type conduction agent and formed over the corresponding P-type well region;
a plurality of N-type source regions, wherein each of the N-type source regions is implanted with the N-type conduction agent at a high doping concentration and formed over the corresponding P-type well region;
a plurality of dielectric layers formed over the corresponding P-type well regions;
a plurality of trench gate layers formed over the N-type drift layer; and
a plurality of PIN diodes, wherein each of the PIN diodes is embedded in the N-type drift layer, and wherein each of the PIN diodes comprises a P-type semiconductor and an N-type semiconductor, the N-type semiconductor is implanted and formed on the top of the P-type semiconductor, and the P-type semiconductor and the N-type semiconductor are in contact, forming an I-type junction.

5. The trench MOSFET of claim 4, wherein material of the substrate and the N-type drift layer is silicon (Si) or silicon carbide (SiC).

6. The trench MOSFET of claim 4, wherein the P-type conduction agent is one of boron ions, indium ions, or gallium ions, and the N-type conduction agent is one of phosphorus ions, arsenic ions, or antimony ions.

7. The trench MOSFET of claim 4, wherein at least one of the PIN diodes is embedded in the N-type drift layer, and an embedded position of each of the at least one of the PIN diodes is located at a middle of the N-type drift layer.

8. The trench MOSFET of claim 4, wherein at least one of the PIN diodes is embedded in the N-type drift layer, and the N-type semiconductor of each of the at least one of the PIN diodes is implanted adjacent to and formed below the corresponding trench gate layer.

9. The trench MOSFET of claim 4, wherein at least one of the PIN diodes is embedded in the N-type drift layer, and the P-type semiconductor of each of the at least one of the PIN diodes is implanted and formed over the substrate.

10. The trench MOSFET of claim 4, wherein the I-type junction is selectively formed through ion implantation using a dopant.

11. The trench MOSFET of claim 10, wherein the dopant is at least one argon ion.

12. A trench metal-oxide-semiconductor field-effect transistor (MOSFET), comprising:
a substrate doped with a P-type conduction agent at a high doping concentration;
a P-type drift layer doped with the P-type conduction agent at a low doping concentration and extending over the substrate;
a plurality of N-type well regions, wherein each of the N-type well regions is doped with an N-type conduction agent at a low doping concentration and extends within the P-type drift layer;
a plurality of N-type contact regions, wherein each of the N-type contact regions is implanted with the N-type conduction agent and formed over the corresponding N-type well region;
a plurality of P-type source regions, wherein each of the P-type source regions is implanted with the P-type conduction agent at a high doping concentration and formed over the corresponding N-type well region;
a plurality of dielectric layers formed over the corresponding N-type well regions;
a plurality of trench gate layers formed over the P-type drift layer; and
a plurality of I-type regions, wherein each of the I-type regions is embedded in the P-type drift layer and implanted with at least one doped ion.

13. The trench MOSFET of claim 12, wherein each of the at least one doped ion in each of the I-type regions is an argon ion.

14. The trench MOSFET of claim 12, wherein material of the substrate and the P-type drift layer is silicon (Si) or silicon carbide (SiC).

15. A trench metal-oxide-semiconductor field-effect transistor (MOSFET), comprising:
a substrate doped with a P-type conduction agent at a high doping concentration;
a P-type drift layer doped with the P-type conduction agent at a low doping concentration and extending over the substrate;
a plurality of N-type well regions, wherein each of the N-type well regions is doped with an N-type conduction agent at a low doping concentration and extends within the P-type drift layer;
a plurality of N-type contact regions, wherein each of the N-type contact regions is implanted with the N-type conduction agent and formed over the corresponding N-type well region;
a plurality of P-type source regions, wherein each of the P-type source regions is implanted with the P-type conduction agent at a high doping concentration and formed over the corresponding N-type well region;
a plurality of dielectric layers formed over the corresponding N-type well regions;
a plurality of trench gate layers formed over the P-type drift layer; and
a plurality of NIP diodes, wherein each of the NIP diodes is embedded in the P-type drift layer, and wherein each of the NIP diodes comprises an N-type semiconductor and a P-type semiconductor, the P-type semiconductor is implanted and formed on the top of the N-type semiconductor, and the N-type semiconductor and the P-type semiconductor are in contact, forming an I-type junction.

16. The trench MOSFET of claim 15, wherein material of the substrate and the P-type drift layer is silicon (Si) or silicon carbide (SiC).

17. The trench MOSFET of claim 15, wherein the P-type conduction agent is one of boron ions, indium ions, or gallium ions, and the N-type conduction agent is one of phosphorus ions, arsenic ions, or antimony ions.

18. The trench MOSFET of claim 15, wherein at least one of the NIP diodes is embedded in the P-type drift layer, and an embedded position of each of the at least one of the NIP diodes is located at a middle of the P-type drift layer.

19. The trench MOSFET of claim 15, wherein at least one of the NIP diodes is embedded in the P-type drift layer, and the N-type semiconductor of each of the at least one of the NIP diodes is implanted adjacent to and formed below the corresponding trench gate layer.

20. The trench MOSFET of claim 15, wherein at least one of the NIP diodes is embedded in the P-type drift layer, and the N-type semiconductor of each of the at least one of the NIP diodes is implanted and formed over the substrate.

21. The trench MOSFET of claim 15, wherein the I-type junction is selectively formed through ion implantation using a dopant.

22. The trench MOSFET of claim 21, wherein the dopant is at least one argon ion.
